(19) United States
(12) Patent Application Publication
(10) Pub. No.: US 2024/0170523 A1
(43) Pub. Date: May 23, 2024

(54) IMAGE SENSORS AND MANUFACTURING METHODS OF THE SAME

(71) Applicant: Samsung Electronics Co., Ltd., Suwon-si (KR)

(72) Inventors: Wonhyeok Kim, Suwon-si (KR); Seungjoo Nah, Suwon-si (KR); Ingyu Hyun, Suwon-si (KR); Heegeun Jeong, Suwon-si (KR)

(21) Appl. No.: 18/509,493

(22) Filed: Nov. 15, 2023

(30) Foreign Application Priority Data
Nov. 18, 2022 (KR) 10-2022-0155794

(51) Int. Cl. H01L 27/146

(52) U.S. Cl. CPC H01L 27/1463; H01L 27/1462; H01L 27/14621; H01L 27/14627; H01L 27/14636; H01L 27/14645; H01L 27/14683

(57) ABSTRACT

An image sensor including a substrate including a first surface and a second surface, and including a plurality of photoelectric conversion elements therein. A plurality of pixels may be provided in the substrate, a plurality of pixel separation structures may be configured to separate the plurality of pixels, and a plurality of contacts may be respectively connected to the plurality of pixel separation structures. A first contact among the plurality of contacts may be configured to apply a current to a first portion of the plurality of pixel separation structures, and a second contact among the plurality of contacts may be configured to detect a current from a second portion of the plurality of pixel separation structures.

### CROSS-REFERENCE TO RELATED APPLICATION

This application is based on and claims priority under 35 U.S.C. § 119 to Korean Patent Application No. 10-2022-0155794, filed on Nov. 18, 2022, in the Korean Intellectual Property Office, and the entire contents of the above-identified application are incorporated by reference herein.

### TECHNICAL FIELD

The inventive concept relates to image sensors, and more particularly, to image sensors including verification pads and contacts, and to manufacturing methods of the image sensors.

### BACKGROUND

Image sensors are devices which capture two-dimensional or three-dimensional images of objects. The image sensors generate images of the objects by using photoelectric conversion elements which react according to intensity of light reflected from the objects. Recently, image sensors based on complementary metal-oxide semiconductor (CMOS) capable of implementing high resolution have become widely used.

### SUMMARY

The present disclosure provides image sensor capable of detecting and/or configured to detect a leakage current, and manufacturing methods of the image sensor.

In addition, the issues to be solved by the technical idea of the inventive concepts provided herein are not limited to those mentioned above, and other issues may be clearly understood by those of ordinary skill in the art from the following descriptions.

According to some aspects of the inventive concepts, there is provided an image sensor including a substrate including a first surface and a second surface, and including a plurality of photoelectric conversion elements therein, a plurality of pixels provided in the substrate, a plurality of pixel separation structures configured to separate the plurality of pixels, and a plurality of contacts respectively connected to the plurality of pixel separation structures, wherein a first contact among the plurality of contacts is configured to apply a current to a first portion of the plurality of pixel separation structures, and a second contact among the plurality of contacts is configured to detect a current from a second portion of the plurality of pixel separation structures.

According to some aspects of the inventive concepts, there is provided an image sensor including a substrate including a first surface and a second surface, the substrate including a plurality of pixels and a plurality of photoelectric conversion elements therein, and the substrate including an active pixel region that defines the plurality of pixels, a dummy pixel region that surrounds the active pixel region, and a pad region arranged on at least one side of the dummy pixel region, an insulating layer arranged on the first surface. A plurality of pixel separation structures may be configured to separate the plurality of pixels, and a plurality of contacts may be respectively connected to the plurality of pixel separation structures, and may extend through the insulating layer, wherein the plurality of pixel separation structures include a pixel separation structure arranged in the active pixel region, and a first verification pixel separation structure and a second verification pixel separation structure arranged in the dummy pixel region. The first verification pixel separation structure may include a first pad having at least a portion thereof extending into the substrate on the first surface, and the second verification pixel separation structure may include a second pad having at least a portion thereof extending into the substrate on the first surface. The first pad may be electrically connected to a first contact, and the second pad may be electrically connected to a second contact. The first contact may be configured to apply a bias voltage to the first verification pixel separation structure, and the second contact may be configured to detect a current from the second verification pixel separation structure.

According to some aspects of the inventive concept, there is provided an image sensor including a substrate including a first surface and a second surface, the substrate including a plurality of pixels and a plurality of photoelectric conversion elements therein, and including an active pixel region that defines the plurality of pixels, a dummy pixel region that surrounds the active pixel region, and a pad region arranged on at least one side of the dummy pixel region, a color filter arranged on the second surface of the substrate, a reflection prevention layer arranged on the color filter, a plurality of micro lenses arranged on the reflection prevention layer, an insulating layer arranged under the first surface, and partially covering a first pad and a second pad, an interlayer insulating layer arranged under the insulating layer, and configured to provide a path to output an electrical signal generated by the plurality of photoelectric conversion elements, a plurality of pixel separation structures that separate the plurality of pixels, and including a pixel separation structure arranged in the active pixel region, and a first verification pixel separation structure and a second verification pixel separation structure arranged in the dummy pixel region, and a plurality of contacts respectively connected to the plurality of pixel separation structures, and extending through the insulating layer and extending into the interlayer insulating layer. The first verification pixel separation structure may include the first pad having at least a portion therein extending into the substrate on the first surface, and the second verification pixel separation structure may include the second pad having at least a portion thereof extending into the substrate on the first surface, and the first pad may be electrically connected to a first contact. The second pad may be electrically connected to a second contact. The first contact may be configured to apply a bias voltage to the first verification pixel separation structure, and the second contact may be configured to detect a current from the second verification pixel separation structure.

### BRIEF DESCRIPTION OF THE DRAWINGS

Embodiments will be more clearly understood from the following detailed description taken in conjunction with the accompanying drawings in which:

FIG. 1 is a block diagram of an image sensor according to some embodiments;

FIG. 2 is a circuit diagram of pixels included in an image sensor according to some embodiments;

FIG. 3 is a plan view of an image sensor according to some embodiments;

FIG. 4 is a plan view of a configuration of an image sensor, according to some embodiments;

FIG. 5 is a cross-sectional view taken along line A-A′ in FIG. 4;

FIG. 6 is a partially enlarged view of region B in FIG. 4;

FIG. 7 is a cross-sectional view taken along line I-I′ in FIG. 6 for describing a portion of a manufacturing process of an image sensor, according to some embodiments;

FIG. 8 is a cross-sectional view taken along line M-M′ in FIG. 6 for describing a portion of a manufacturing process of an image sensor, according to some embodiments;

FIG. 9 is a flowchart of a manufacturing method of an image sensor, according to some embodiments;

FIGS. 10A, 10B, 10C, 10D, and 10E are cross-sectional views for describing a manufacturing method of an image sensor, according to some embodiments;

FIG. 11 is a block diagram of an electronic device including a multi-camera module;

FIG. 12 is a detailed block diagram of a camera module in FIG. 11; and

FIG. 13 is a block diagram of a configuration of an image sensor, according to some embodiments.

### DETAILED DESCRIPTION OF THE EMBODIMENTS

Hereinafter, some embodiments of the inventive concepts will be described in detail with reference to the accompanying drawings. Identical reference numerals may be used for the same constituent elements in the drawings, and duplicate descriptions thereof may be omitted herein in the interest of brevity.

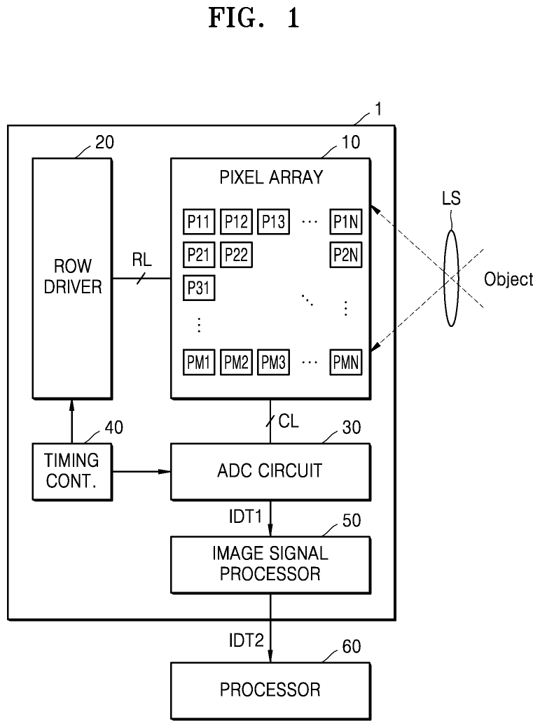

FIG. 1 is a block diagram of an image sensor 1 according to some embodiments.

Referring to FIG. 1, the image sensor 1 according to an embodiment may be mounted on an electronic equipment and may be capable of sensing an image or light. For example, the image sensor 1 may be applied to an electronic device, such as a camera, a smart phone, a wearable device, Internet of Things (IOT), a personal computer (PC), a personal digital assistant (PDA), a portable multimedia player (PMP), and/or a navigation device, as non-limiting examples of electronic devices. In addition, the image sensor 1 may be utilized in vehicles, furniture, manufacturing equipment, doors, various measuring instruments, or the like.

The image sensor 1 may include a pixel array 10, a row driver 20, an analog-digital converting circuit (hereinafter, an ADC circuit) 30, a timing controller 40, an image signal processor 50.

The pixel array 10 may receive an optical signal of light that is incident thereon via a lens LS, the light being reflected by an object. The pixel array 10 may convert the optical signal to an electrical signal. The pixel array 10 may be implemented as a complementary metal-oxide semiconductor (CMOS) image sensor, but the present disclosure is not limited thereto. The pixel array 10 may also include a portion of a charge coupled device (CCD) chip.

The pixel array 10 may be connected to a plurality of row lines RL and a plurality of column lines CL (or referred to as an output line), and may include a plurality of pixels P11, P12, P13, . . . , PIN, P21, P22, . . . , P2N, P31, . . . , PM1, PM2, PM3, . . . , PMN (hereinafter, P11 through PMN). Each of the pixels P11 through PMN is connected to one of the plurality of row lines RL and to one of the plurality of column lines CL, and arranged in M rows and N columns. In the present embodiment, the number of the plurality of pixels P11 through PMN may be MxN.

Each of the plurality of pixels P11 through PMN may sense an optical signal to be received by using a photoelectric conversion element. The plurality of pixels P11 through PMN may detect a light amount of an optical signal, and output an electrical signal representing the detected light amount.

The row driver 20 may generate a plurality of control signals configured to control or capable of controlling operations of the plurality of pixels P11 through PMN arranged on each row, according to a control of the timing controller 40. The row driver 20 may provide a plurality of control signals respectively via the plurality of row lines RL to each of the plurality of pixels P11 through PMN of the pixel array 10. The pixel array 10 may be driven in row units, in response to the plurality of control signals provided by the row driver 20.

The pixel array 10 may output the plurality of sensing signals respectively via the plurality of column lines CL according to a control of the row driver 20.

The ADC circuit 30 may perform an analog-digital conversion on each of the plurality of sensing signals received respectively via the plurality of column lines CL. The ADC circuit 30 may include the ADC corresponding to each of the plurality of column lines CL, and the ADC may convert, to a pixel value, the sensing signal received via a corresponding column line CL. According to an operation mode of the image sensor 1, the pixel value may represent the light amount sensed by the plurality of pixels P11 through PMN.

The ADC may include a correlated double sampling (CDS) circuit for sampling and holding a received signal. The CDS circuit may perform double sampling on a noise signal and a sensing signal when the plurality of pixels P11 through PMN are in a reset state, and may output a signal corresponding to a difference between the sensing signal and the noise signal. The ADC may include a counter, and the counter may generate a pixel value by counting the number of signals received from the CDS circuit. For example, the CDS circuit may be implemented as an operational transconductance amplifier (OTA), a differential amplifier, etc. The counter may be implemented as, for example, an up-counter and a computation circuit, an up/down counter, a bit-wise inversion counter, etc.

The timing controller 40 may generate timing control signals used to control operations of the row driver 20 and the ADC circuit 30. The row driver 20 may drive the pixel array 10 in row units, as described above, based on the timing control signals output by the timing controller 40, and in addition, the ADC driver 30 may convert, to the pixel values, the plurality of sensing signals received via the plurality of column lines CL, based on the timing control signals output by the timing controller 40.

The image signal processor 50 may receive a first image data IDT1, for example, unprocessed image data, output by the ADC circuit 30, and may perform signal processing on the first image data IDT1. The image signal processor 50 may perform signal processing, such as black level compensation, lens shading compensation, cross talk compensation, and bad pixel correction.

A second image data IDT2 output by the image signal processor 50, for example, signal-processed image data, may be transmitted to a processor 60. The processor 60 may include a host processor of an electronic device on which the image sensor 1 is mounted.

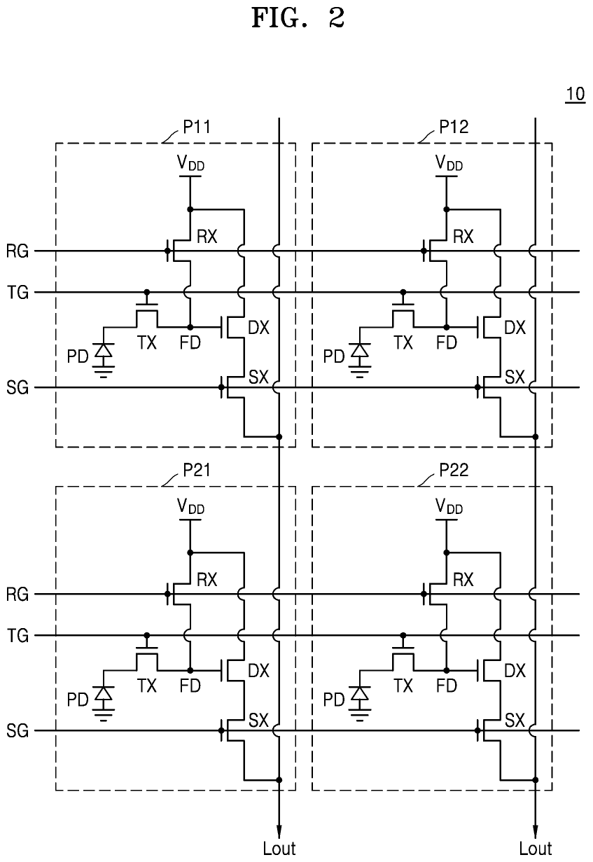

FIG. 2 is a circuit diagram for describing pixels P11, P12, P21, and P22 included in the image sensor 1, according to some embodiments.

Referring to FIGS. 1 and 2, the pixel array 10 may include the pixels P11, P12. P21, and P22. The pixels P11, P12, P21, and P22 may be arranged in a matrix form. For convenience of illustration, only four pixels P11, P12, P21, and P22 are illustrated in FIG. 2, but the description thereof may be similarly applied to each of the plurality of pixels P11 through PMN included in the pixel array 10.

According to some embodiments, each of the pixels P11, P12, P21, and P22 may include a transmission transistor TX and logic transistors RX, SX, and DX. In this case, the logic transistors RX, SX, and DX may include a reset transistor RX, a selection transistor SX, and a drive transistor DX.

A photoelectric conversion element PD may generate and accumulate photocharges in proportion to an amount of light incident from the outside (e.g., an amount of light from a light source external to the pixel array 10). The photoelectric conversion element PD may include a photo-sensing element that includes an organic material or an inorganic material, such as an inorganic photo diode, an organic photo diode, a Perovskite photo diode, a photo transistor, a photo gate, and/or a pinned photo diode.

In response to a signal received at a transmission gate TG thereof, the transmission transistor TX may transmit electric charges accumulated in the photoelectric conversion element PD to a floating diffusion region FD based on a transmission signal. The optical charge generated by the photoelectric conversion element PD may be stored in the floating diffusion region FD. The drive transistor DX may be controlled by the amount of optical charge accumulated in the floating diffusion region FD.

The reset transistor RX may periodically reset the charges accumulated in the floating diffusion region FD based on a reset signal RG. A drain electrode of the reset transistor RX may be connected to the floating diffusion region FD, and a source electrode thereof may be connected to a power voltage VDD. When the reset transistor RX is turned on, the power voltage VDD connected to the source electrode of the reset transistor RX may be transferred to the floating diffusion region FD. Accordingly, when the reset transistor RX is turned on, the charges accumulated in the floating diffusion region FD may be discharged, and the floating diffusion region FD may be reset.

The drive transistor DX may constitute a source follower buffer amplifier together with a static current source outside each of the pixels P11, P12, P21, and P22, and may amplify a voltage change in the floating diffusion region FD and output the amplified voltage change to an output line Lout.

The selection transistor SX may select pixels P11, P12, P21, and P22 to read photoelectric signal values sensed in row units based on a selection signal SG. When the selection transistor SX is turned on, the power voltage VDD may be transferred to a source electrode of the drive transistor DX.

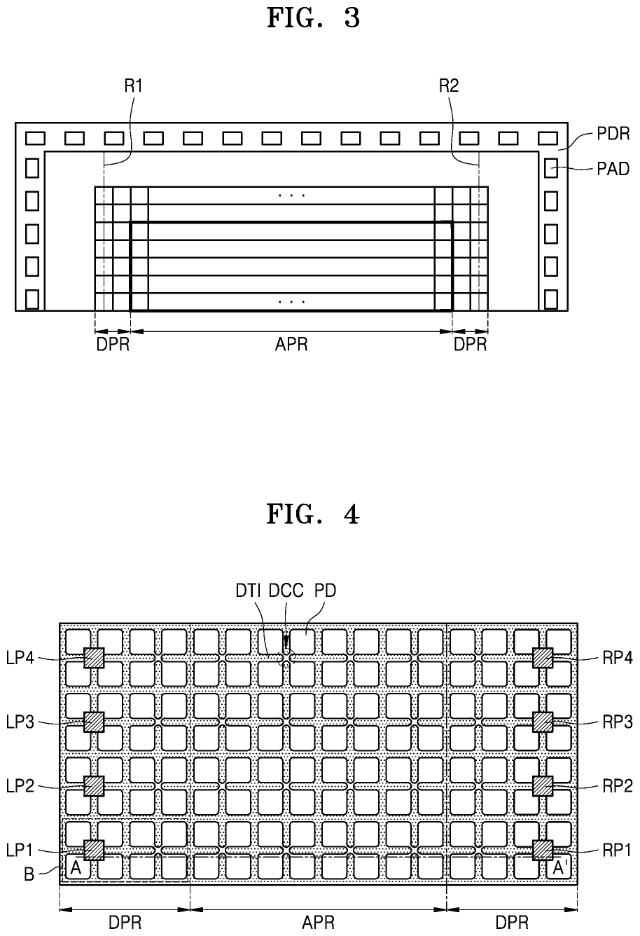

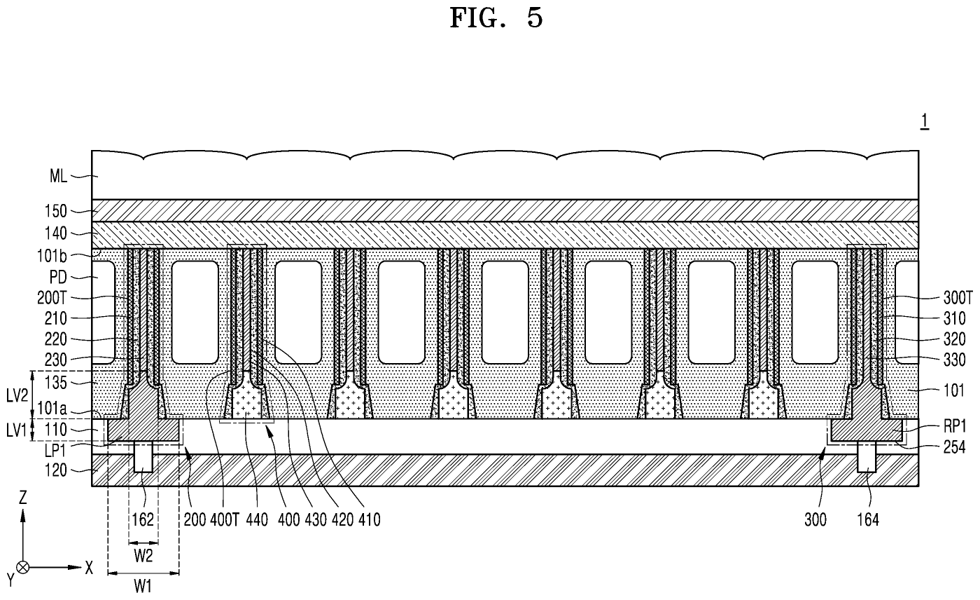

FIG. 3 is a plan view of the image sensor 1 according to some embodiments. FIG. 4 is a plan view of a configuration of the image sensor 1, according to some embodiments. FIG. 5 is a cross-sectional view taken along line A-A′ in FIG. 4.

Referring to FIGS. 3, 4, and 5, the pixel array 10 of the image sensor 1 (refer to FIG. 1) may include a substrate 101, the photoelectric conversion element PD, a gate electrode (not illustrated), an insulating layer 110, a contact via (not illustrated), conductive patterns (not illustrated), an interlayer insulating layer 120, a first verification pixel separation structure 200, a second verification pixel separation structure 300, a pixel separation structure 400, a color filter 140, a reflection prevention layer 150, a planarization layer (not illustrated), and a plurality of micro lenses ML. The image sensor 1 may include a plurality of pixel separation structures, and may include a plurality of pads LP2, LP3, LP4, RP2, RP3, and RP4 in addition to a first pad LP1 and a second pad RP1.

The substrate 101 may include a first surface 101a and a second surface 101b facing each other. The first surface 101a of a substrate may be a front surface of the substrate 101, and the second surface 101b of the substrate may be a back surface of the substrate 101.

Two directions substantially in parallel with the first surface 101a and substantially perpendicular to each other may be defined as an X direction and a Y direction, and a direction substantially perpendicular to the first surface 101a may be defined as a Z direction. The X direction, the Y direction, and the Z direction may be substantially perpendicular to each other. In this case, the X direction may be referred to as a first direction, the Z direction may be referred to as a second direction, and the Y direction may be referred to as a third direction.

A plurality of pixels P11, P12, P13, P14, P21, P22, P23, P24, P31, P32, P33, P34, P41, P42, P43, and P44 (hereinafter, referred to as P11 through P44) may be formed in the substrate 101. The plurality of pixels P11 through P44 may be arranged in a matrix form in a plan view.

A plurality of dummy pixels may be formed in a dummy pixel region DPR in the substrate. According to some embodiments, the plurality of pixels P11 through P44 may be arranged at a center portion of the matrix, and dummy pixels may be arranged on edges thereof.

The first verification pixel separation structure 200 and the second verification pixel separation structure 300 may be arranged in the dummy pixel region DPR in the substrate 101. Dummy pixels in the dummy pixel region DPR may be defined by the first verification pixel separation structure 200 and the second verification pixel separation structure 300.

The first verification pixel separation structure 200 may include a first external insulating liner 210, a first internal insulating liner 220, a first conductive layer 230, and a plurality of first pads LP1. The first conductive layer 230 may be arranged inside a first dummy pixel trench 200T that penetrates or extends through the substrate 101 in the second direction. The first external insulating liner 210 may be arranged on a portion of an inner wall of the first dummy pixel trench 200T that penetrates or extends through the substrate 101. A portion of the first internal insulating liner 220 may be arranged between the first conductive layer 230 and the first external insulating liner 210. The first internal insulating liner 220 may be arranged on a portion of the inner wall of the pixel trench 200T, and may extend from the first surface 101a of the substrate 101 to the second surface 101b. The second verification pixel separation structure 300 may include a second external insulating liner 310, a second internal insulating liner 320, a second conductive layer 330, and a second pad RP1. The second verification pixel separation structure 300 may have the same structure or similar structure as the first verification pixel separation structure 200.

The pixel separation structure 400 may be arranged in the substrate 101 in the dummy pixel region DPR or in an active pixel region APR. The plurality of pixels P11 through P44 may be defined by the pixel separation structure 400. The pixel separation structure 400 may include an external insulating liner 410, an internal insulating liner 420, a conductive layer 430, and a lower insulating layer 440. The conductive layer 430 may be arranged inside a pixel trench 400T that penetrates or extends through the substrate 101 in the second direction. The external insulating liner 410 may be arranged on a portion of an inner wall of the pixel trench 400T that penetrates or extends through the substrate 101. A portion of the internal insulating liner 420 may be arranged between the conductive layer 430 and the external insulating liner 410. The internal insulating liner 420 may be arranged on a portion of the inner wall of the pixel trench 400T, and may extend from the first surface 101a of the substrate 101 to the second surface 101b.

In some embodiments, the first conductive layer 230, the second conductive layer 330, and the conductive layer 430 may include at least one of doped polysilicon, a metal, metal silicide, metal nitride, or a metal-included layer. The first external insulating liner 210, the first internal insulating liner 220, the second external insulating liner 310, the second internal insulating liner 320, the external insulating liner 410, and the internal insulating liner 420 may include metal oxides, such as hafnium oxide, aluminum oxide, and tantalum oxide.

In this case, the first external insulating liner 210, the first internal insulating liner 220, the second external insulating liner 310, the second internal insulating liner 320, the external insulating liner 410, and the internal insulating liner 420 may act as negative fixed charge layers. In other embodiments, the first external insulating liner 210, the first internal insulating liner 220, the second external insulating liner 310, the second internal insulating liner 320, the external insulating liner 410, and the internal insulating liner 420 may include insulating materials, such as silicon oxide, silicon nitride, and silicon oxynitride. The lower insulating layer 440 may include an insulating material, such as silicon oxide, silicon nitride, and silicon oxynitride.

According to some embodiments, the photoelectric conversion element PD, for example, a photodiode, may be formed in the substrate 101. The gate electrodes (not illustrated) may be arranged apart from each other on the first surface 101a of the substrate 101. The gate electrode may include, for example, any one of a gate electrode of the transmission transistor TX, a gate electrode of the reset transistor RX, and a gate electrode of the drive transistor DX in FIG. 2. The gate electrode may be arranged on the first surface 101a of the substrate 101, or may be buried in the substrate 101.

The interlayer insulating layer 120 and the conductive patterns may be arranged on the first surface 101a of the substrate 101. The conductive patterns may be covered by the interlayer insulating layer 120. The conductive patterns may be protected and insulated by the interlayer insulating layer 120.

The interlayer insulating layer 120 may include, for example, silicon oxide, silicon nitride, silicon oxynitride, etc. The conductive patterns may include, for example, aluminum (Al), copper (Cu), tungsten (W), cobalt (Co), ruthenium (Ru), etc.

The conductive patterns may include a plurality of wirings stacked and at different levels. In FIG. 4, the conductive patterns are illustrated to include three layers sequentially stacked, but the present disclosure is not limited thereto. For example, conductive patterns of two or more layers or four or more layers may also be formed in the interlayer insulating layer 120.

The insulating layer 110 may be arranged between the first surface 101a of the substrate 101 and the interlayer insulating layer 120. The insulating layer 110 may cover the gate electrode arranged on the first surface 101a of the substrate 101. According to some embodiments, the insulating layer 110 may include an insulating material, such as silicon oxide, silicon nitride, and silicon oxynitride.

The color filter 140 may be arranged on the second surface 101b of the substrate 101. The color filter 140 may be configured to transfer light of the same or different wavelength bands to each of the plurality of pixels P11 through P44. According to some embodiments, a portion of the color filter 140 overlapping the plurality of pixels P11 through P44 may include color filters of the plurality of pixels P11 through P44 overlapping each other.

The reflection prevention layer 150 may include a transparent insulating layer of an oxide layer type. In some embodiments, the reflection prevention layer 150 may include one or more of hafnium oxide (HfO₂), silicon nitride (SiN), aluminum oxide (Al₂O₃), zirconium oxide (ZrO₂), tantalum oxide (Ta₂O₅), titanium oxide (TiO₂), lanthanum oxide (La₂O₃), praseodymium oxide (Pr₂O₃), cerium oxide (CeO₂), neodymium oxide (Nd₂O₃), promethium oxide (PM₂O₃), samarium oxide (Sm₂O₃), europium oxide (Eu₂O₃), gadolinium oxide (Gd₂O₃), terbium oxide (Tb₂O₃), dysprosium oxide (Dy₂O₃), holmium oxide (H_{O2}O₃), thulium oxide (Tm₂O₃), ytterbium oxide (Yb₂O₃), ruthenium oxide (Lu₂O₃), and/or yttrium oxide (Y₂O₃). The reflection prevention layer 150 may include a single layer including any one of the materials described above or a multilayer in which one or more of the materials described above are stacked. For example, the reflection prevention layer 150 may have transmittance to light having a wavelength band of visible light.

Optionally, the planarization layer (not illustrated) may cover the reflection prevention layer 150. The planarization layer may include, for example, an oxide layer, a nitride layer, a low dielectric material, or resin. According to some embodiments, the planarization layer may have a multilayer structure.

In addition, the image sensor 1 may include a first verification wiring R1 and a second verification wiring R2 electrically connecting a first contact 162 and a second contact 164 to a pad region PDR. The pad region PDR may be arranged on at least one side of the active pixel region APR, for example, on four side surfaces of the active pixel region APR in a plan view. A plurality of pads PAD may be arranged in the pad region PDR, and may be configured to transceive electrical signals to and from an external device. In this case, the image sensor 1 may apply a bias voltage to the first contact 162 via the first verification wiring R1, and the amount of leakage current in the substrate 101 may be measured or detected at the second contact 164 via the second verification wiring R2.

In this case, the first contact 162 among a plurality of contacts may apply a current to any one pixel separation structure of a plurality of pixel separation structures. For example, the first contact 162 may apply a current to the first verification pixel separation structure 200. The first verification pixel separation structure 200 may be referred to as a first portion. In addition, the second contact 164 among the plurality of contacts may detect a current from the other pixel separation structure among the plurality of pixel separation structures. For example, the second contact 164 may detect a current from the second verification pixel separation structure 300. The second verification pixel separation structure 300 may be referred to as a second portion.

The plurality of micro lenses ML may be arranged on the reflection prevention layer 150 (or selectively, on the planarization layer). The plurality of micro lenses ML may include an organic material such as a photosensitive resin, or an inorganic material. The plurality of micro lenses ML may condense light incident thereto onto the photoelectric conversion element PD. Each of the plurality of micro lenses ML may vertically overlap a corresponding one of the photoelectric conversion elements PD. Accordingly, one of the plurality of micro lenses ML and one of the photoelectric conversion elements PD may be arranged in each of the plurality of pixels P11 through P44.

In this manner, by forming a plurality of pads (for example, the first pad LP1 and the second pad RP1), a plurality of contacts (for example, the first contact 162 and the second contact 164), and verification wirings (for example, the first verification wiring R1 and the second verification wiring R2) for the pixel separation structure, the image sensor 1 according to the inventive concepts may detect a leakage current therein, and prevent defects thereof. In addition, the leakage current may be detected by forming the plurality of pads, the plurality of contacts, the verification wirings, or the like before forming the color filter 140, the reflection prevention layer 150, and the plurality of micro lenses ML. In this manner, it may be possible to detect and compensate for the defects of the image sensor 1 during formation processes, rather than after all processes for manufacturing the image sensor 1 are performed. Accordingly, the reliability of the image sensor 1 may be improved.

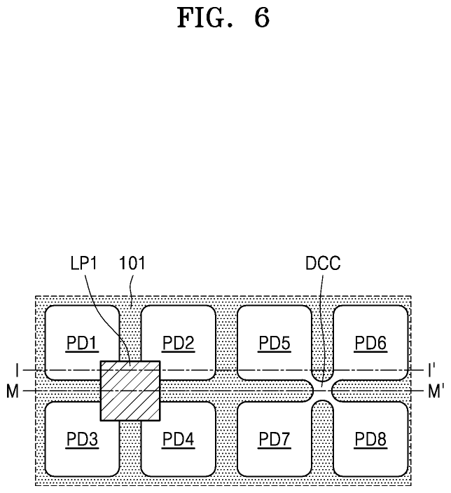

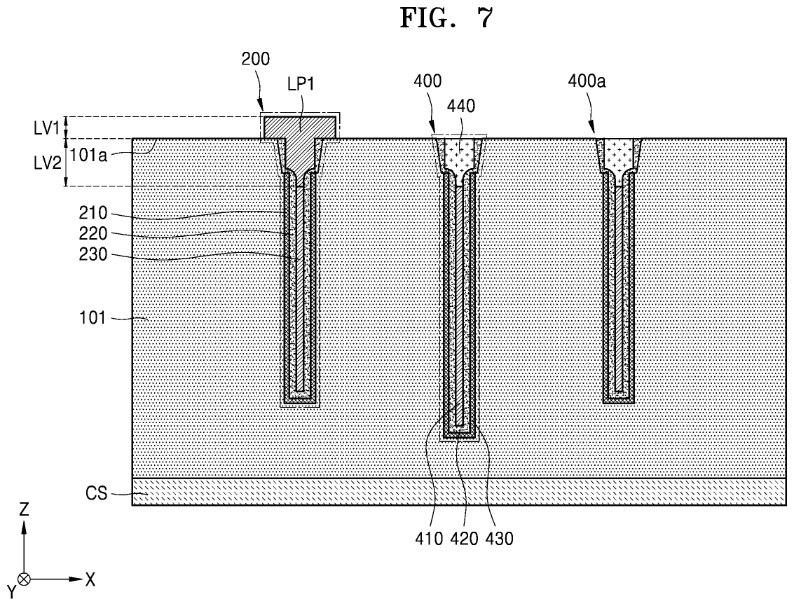

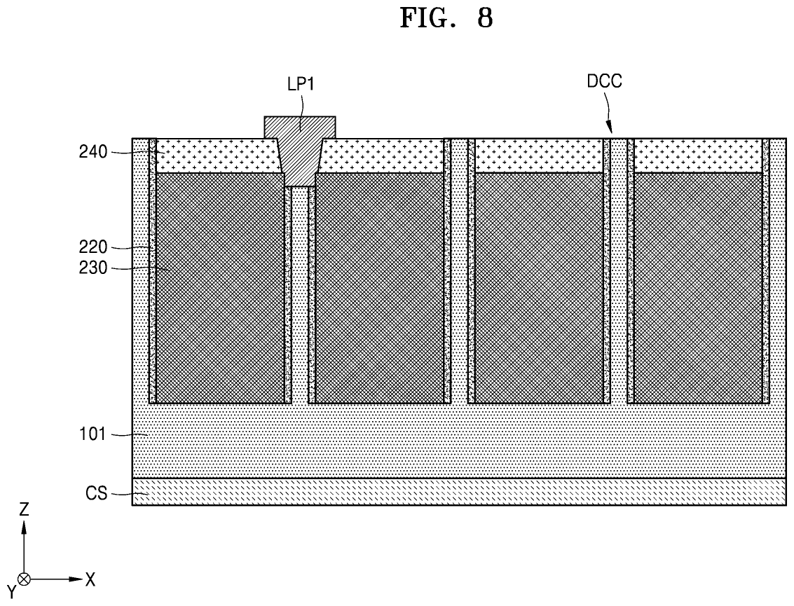

FIG. 6 is a partially enlarged view of region B in FIG. 4. FIG. 7 is a cross-sectional view taken along line I-I′ in FIG. 6 for describing a portion of a manufacturing process of the image sensor 1, according to some embodiments. FIG. 8 is a cross-sectional view taken along line M-M′ in FIG. 6 for describing a portion of a manufacturing process of the image sensor 1, according to some embodiments. Below, descriptions are given with reference to FIGS. 4 and 5 together, and duplicate descriptions already given with reference to FIGS. 4 and 5 are briefly described or omitted.

Referring to FIGS. 4, 6, and 7, the first pad LP1 of the first verification pixel separation structure 200 may be arranged to partially overlap a plurality of photodiodes PD1, PD2, PD3, and PD4. A first horizontal portion of a first vertical level LV1 of the first pad LP1 may have a square or rectangular shape in a plan view. In some embodiments, the first pad LP1 may have a tapered shape in one or more directions. Each of the four corner portions of the first pad LP1 may vertically overlap a portion of each of the plurality of photodiodes PD1, PD2, PD3, and PD4. The structures of the first pad LP1 and the second pad RP1 may be the same. Accordingly, descriptions of the second pad RP1 are omitted.

The first pad LP1 may include a first horizontal portion arranged at the first vertical level LV1 in the second direction of FIG. 5, and a first vertical portion arranged at a second vertical level LV2 in the second direction. The first horizontal portion of the first pad LP1 may be arranged inside the insulating layer 110, and the first vertical portion of the first pad LP1 may extend into the inside of the substrate 101. A horizontal width W1 of the first horizontal portion in the first direction in parallel with the first surface 101a may be greater than a horizontal width W2 of the first vertical portion in the first direction.

Referring to FIG. 7, FIG. 7 illustrates a state in which the first verification pixel separation structure 200 and a plurality of pixel separation structures 400 and 400a are formed on the substrate 101 before the plurality of photodiodes PD1, PD2, PD3, and PD4 are formed. The substrate 101 may be stacked on a carrier substrate CS, and the first verification pixel separation structure 200 and the plurality of pixel separation structures 400 and 400a may be formed in the substrate 101. After the first verification pixel separation structure 200 is formed, the plurality of photodiodes PD1, PD2, PD3, and PD4 may be formed in the substrate 101.

The first pad LP1 formed in this manner may penetrate or extend through the first surface 101a of the substrate 101. The height of a lowermost surface of the first verification pixel separation structure 200 may be different from the height of a lowermost surface of the pixel separation structure 400. For example, the height of the lowermost surface of the first verification pixel separation structure 200 may be less than the height of the lowermost surface of the pixel separation structure 400. In addition, the plurality of pixel separation structures 400 and 400a may have different lowermost surface heights from each other.

Referring to FIGS. 6 and 8, the first verification pixel separation structure 200 may include a first dummy insulating layer 240 in a cross-sectional view taken along cutting line M-M′. The first dummy insulating layer 240 may surround the first vertical portion of the first pad LP1. The first pad LP1 may penetrate or extend through the first dummy insulating layer 240. In this case, a portion of the first conductive layer 230 may be in contact with the first dummy insulating layer 240 and the first pad LP1. The first pad LP1 may include the same material as the first conductive layer 230, and may be electrically connected to the first conductive layer 230. The first internal insulating liner 220 may be in contact with the first conductive layer 230 and the first dummy insulating layer 240. The first pad LP1 may not be formed in the central region DCC of the pixel separation structure on the right side of the first verification pixel separation structure 200. The second verification pixel separation structure 300 may have the same shape as the first verification pixel separation structure 200, and thus, descriptions thereof are omitted here.

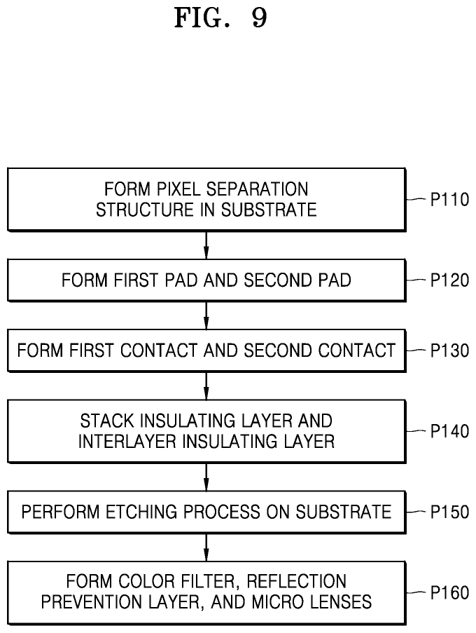

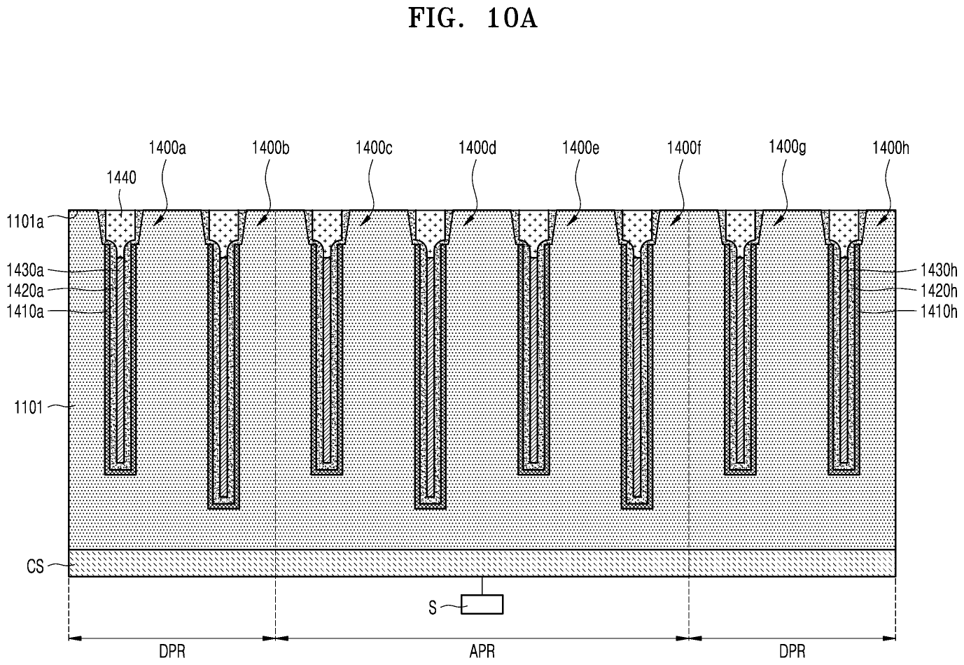

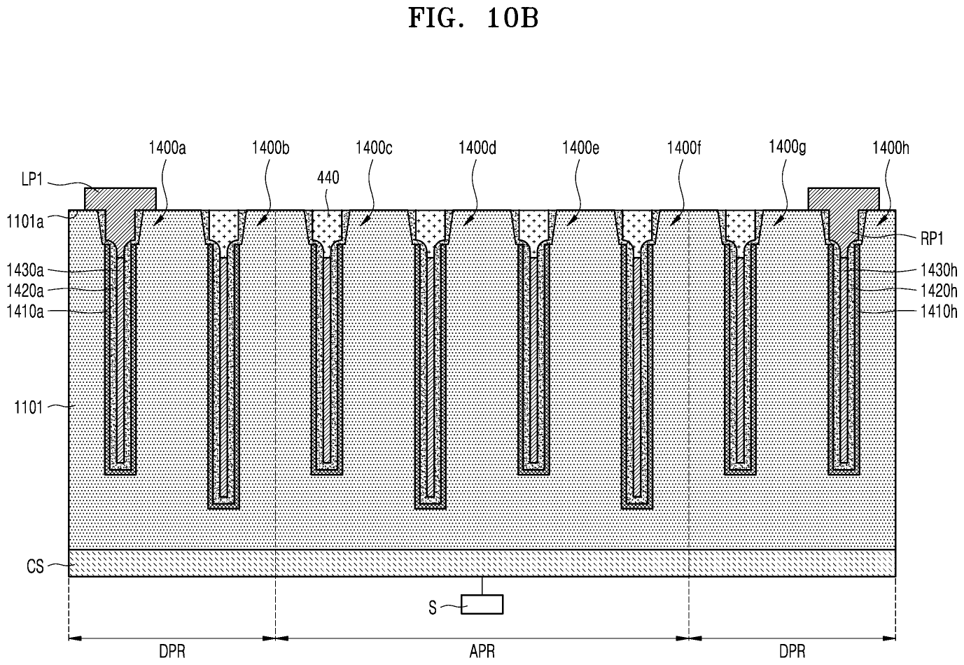

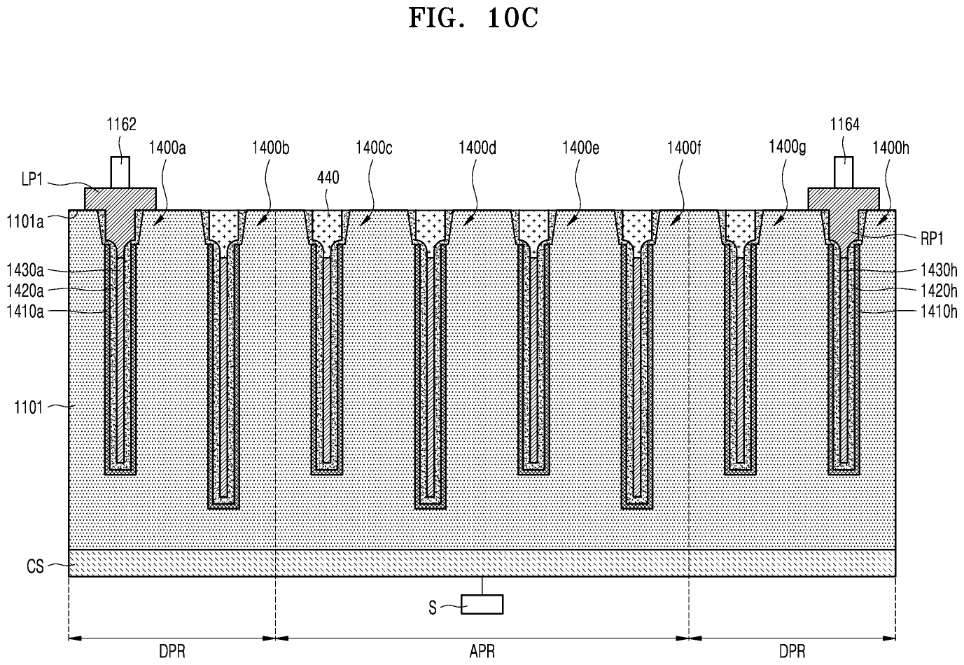

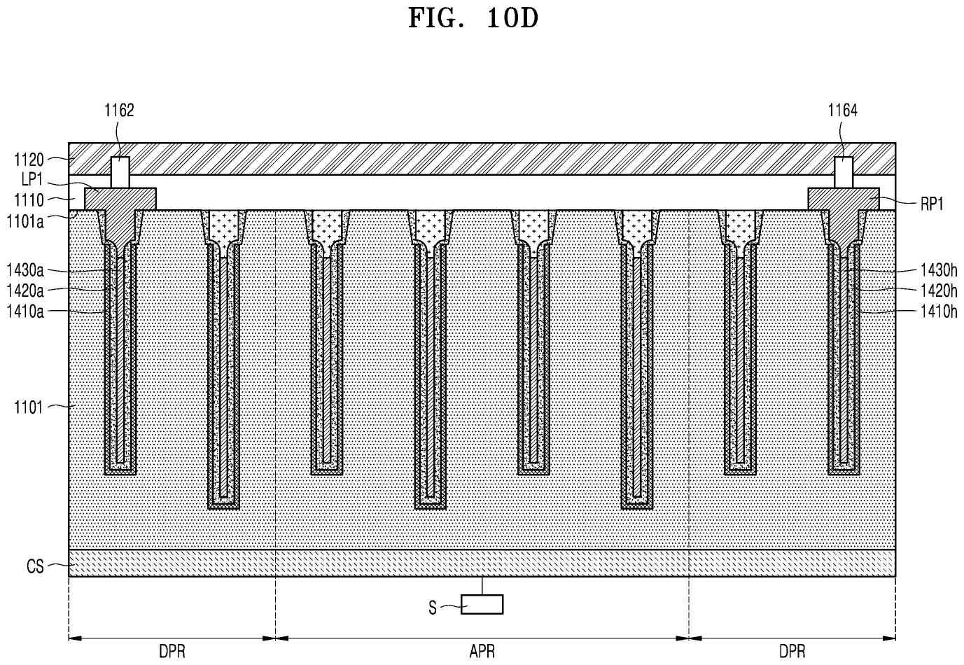

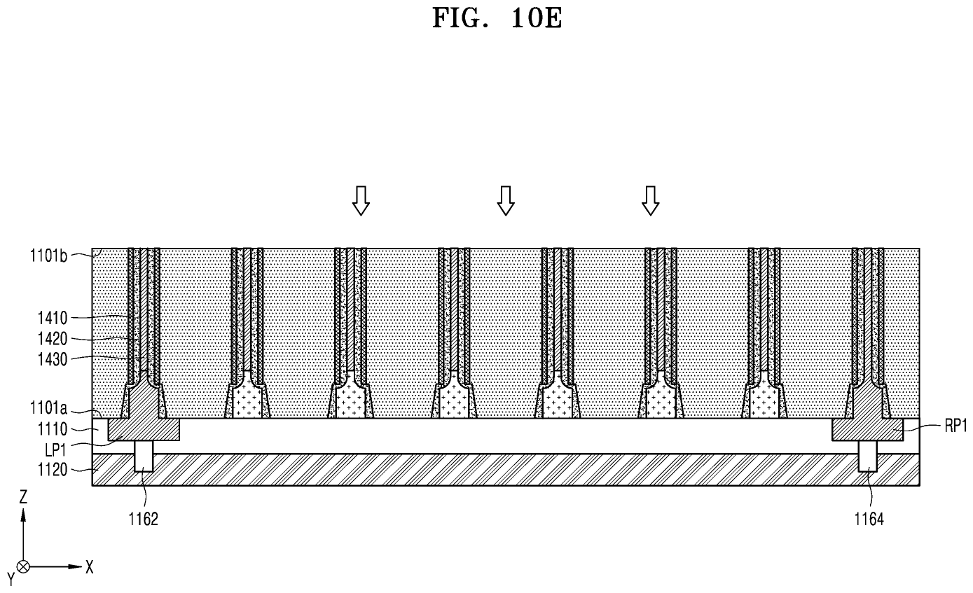

FIG. 9 is a flowchart of a manufacturing method of an image sensor, according to some embodiments. FIGS. 10A through 10E are cross-sectional views for describing a manufacturing method of an image sensor, according to some embodiments.

Referring to FIGS. 9 and 10A, a plurality of pixel separation structures 1400a, 1400b, 1400c, 1400d, 1400e, 1400f, 1400g, and 1400h may be formed in a substrate 1101 (P110). In this case, the substrate 1101 may be stacked on the carrier substrate CS. The carrier substrate CS may include any material having stability with respect to subsequent processes, etc. In some embodiments, when the carrier substrate CS is to be separated and removed by laser ablation, the carrier substrate CS may include a light-transmitting substrate. In some other embodiments, when the carrier substrate CS is to be separated and removed by heating, the carrier substrate CS may include a heat resistant substrate. For example, the carrier substrate CS may include a semiconductor substrate, a ceramic substrate, or a glass substrate.

A plurality of pixel separation structures, for example, first through eighth pixel separation structure 1400a, 1400b, 1400c, 1400d, 1400e, 1400f, 1400g, and 1400h, may be formed in the dummy pixel region DPR and the active pixel region APR. For example, the first pixel separation structure 1400a, the second pixel separation structure 1400b, the seventh pixel separation structure 1400g, and the eighth pixel separation structure 1400h may be formed in the dummy pixel region DPR. In addition, the third through sixth pixel separation structures 1400c, 1400d, 1400e, and 1400f may be formed in the active pixel region APR. The first through eighth pixel separation structures 1400a, 1400b, 1400c, 1400d, 1400e, 1400f, 1400g, and 1400h may have different vertical depths from each other in the substrate 1101. In an example, the first pixel separation structure 1400a may include an external insulating liner 1410a, an internal insulating liner 1420a, a conductive layer 1430a, and a lower insulating layer 1440. The first pixel separation structure 1400a may have the same structure as the pixel separation structure 400 in FIG. 5, and therefore duplicate descriptions thereof are omitted here.

Referring to FIGS. 9 and 10B, the first through eighth pixel separation structures 1400a, 1400b, 1400c, 1400d, 1400e, 1400f, 1400g, and 1400h may be formed (e.g., from a first surface 1101a of the substrate 1101), and then the first pad LP1 and the second pad RP1 may be formed (P120). For example, to form the first pad LP1, the lower insulating layer 1440 of the first pixel separation structure 1400a may be etched first. After the lower insulating layer 1440 is completely etched, the first vertical portion (refer to FIG. 1) of the first pad LP1 may be formed, and the first horizontal portion (refer to FIG. 1) of the first pad LP1 may be formed on the substrate 101. The second pad RP1 may be formed on the eighth pixel separation structure 1400h, and the forming method of the second pad RP1 may be the same as the forming method of the first pad LP1.

Referring to FIGS. 9 and 10C, after the first pad LP1 and the second pad RP1 are formed, a first contact 1162 and a second contact 1164 may be formed (P130). The first contact 1162 may be formed to be in contact with one side surface of the first pad LP1. In addition, the second contact 1164 may be formed to be in contact with one side surface of the second pad RP1. The first contact 1162 may be electrically connected to the first pad LP1, and the second contact 1164 may be electrically connected to the second pad RP1. The first contact 1162 may be connected to a first conductive layer 1430a of the first pixel separation structure 1400a via the first pad LP1. The second contact 1164 may be connected to an eighth conductive layer 1430h of the eighth pixel separation structure 1400h via the second pad RP1.

In this case, the carrier substrate CS may be connected to a sensor S. As the first pad LP1, the second pad RP1, the first contact 162, and the second contact 164 are formed, a leakage current in the sensor S in the substrate 1101 may be detected before subsequent processes are performed.

Referring to FIGS. 9 and 10D, after the first contact 1162 and the second contact 1164 are formed, an insulating layer 1110 and an interlayer insulating layer 1120 may be formed (P140). The insulating layer 1110 and the interlayer insulating layer 1120 may be stacked on the substrate 1101, and the insulating layer 1110 may be arranged between the substrate 1101 and the interlayer insulating layer 1120.

Referring to FIGS. 9 and 10E, an etching process may be performed on the substrate 1101 (P150). Before the etching process is performed, the carrier substrate CS may be removed. Thereafter, the substrate 1101 may be overturned and an etching process may be performed in the second direction (for example, in the Z direction). In this manner, a vertical depth in the substrate 1101 of each of the first through eighth pixel separation structures 1400a, 1400b, 1400c, 1400d, 1400e, 1400f, 1400g, and 1400h may be formed equally.

Referring to FIGS. 5 and 9, a color filter 1140, a reflection prevention layer 1150, and micro lenses ML may be formed (P160). The color filter 140, the reflection prevention layer 150, and the micro lenses ML may be stacked in order on a second surface 1101b of the substrate 1101 on which an etching process has been performed. In this manner, the image sensor 1 may be formed.

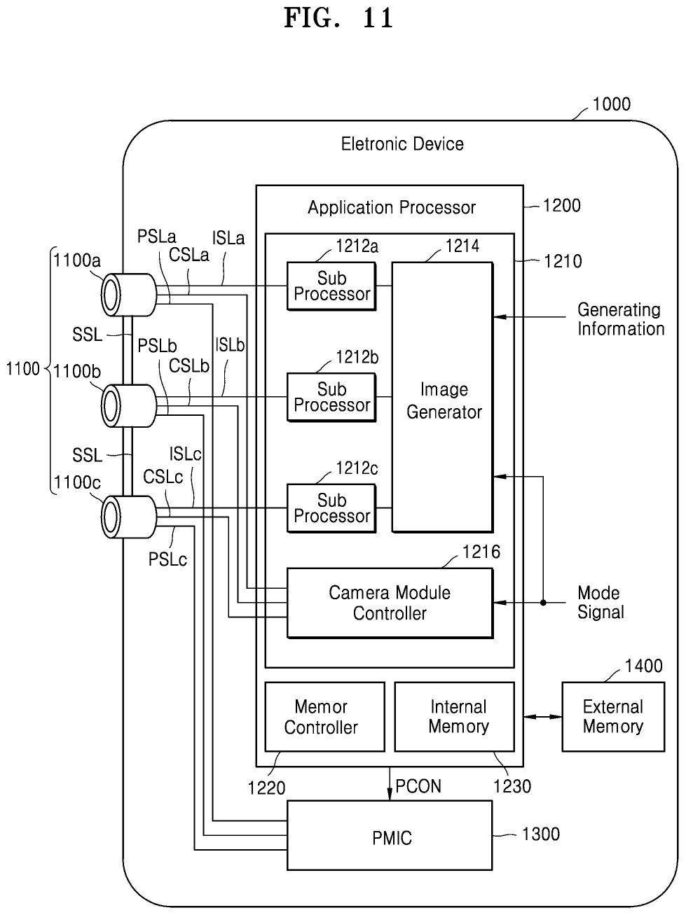

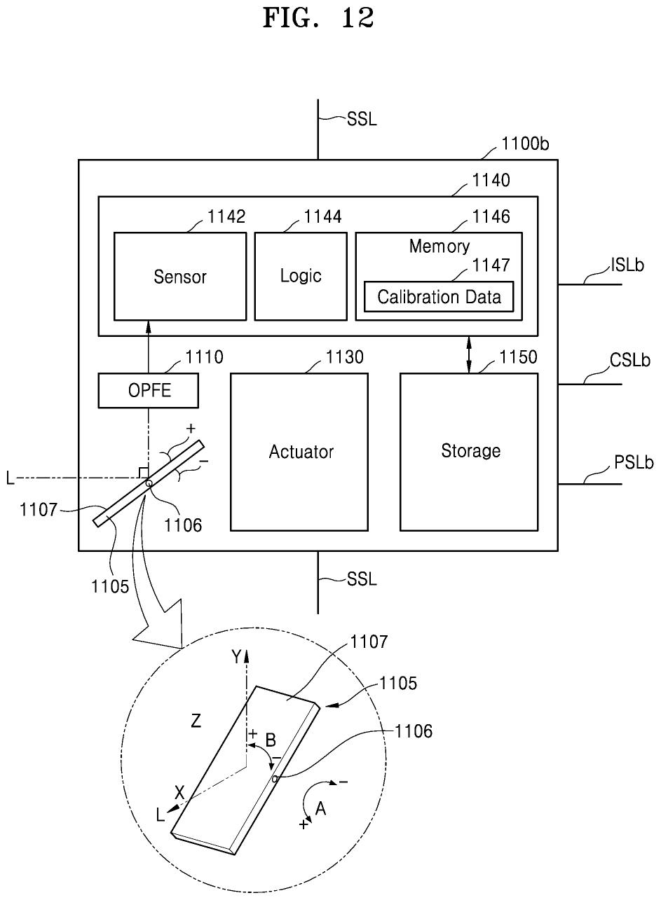

FIG. 11 is a block diagram of an electronic device 1000 including a multi-camera module 1100, and FIG. 12 is a detailed block diagram of a camera module 1100b in FIG. 11.

Referring to FIG. 11, the electronic device 1000 may include the camera module group 1100, an application processor 1200, a power management integrated circuit (PMIC) 1300, and an external storage 1400.

The camera module group 1100 may include a plurality of camera modules 1100a, 1100b, and 1100c. The drawing illustrates an embodiment in which three camera modules 1100a, 1100b, and 1100c are arranged, but the present disclosure is not limited thereto. In some embodiments, the camera module group 1100 may include only two camera modules, or may be modified and embodied to include n (wherein n is a natural number of 4 or more) camera modules.

Referring to FIG. 12, the camera module 1100b may include a prism 1105, an optical path folding element (hereinafter, referred to as OPFE) 1110, an actuator 1130, an image sensing device 1140, and a storage 1150.

A detailed configuration of the camera module 1100b is to be described, but the descriptions below may be applied in the same manner to other camera modules, for example, 1100a and 1100c according to some embodiments.

The prism 1105 may include a reflective surface 1107 of a light reflecting material, and change a path of light L incident from the outside.

In some embodiments, the prism 1105 may change the path of the light L incident in the first direction (X direction) to the second direction (Y direction) perpendicular to the first direction (X direction). In addition, the prism 1105 may rotate the reflective surface 1107 of the light reflecting material to a direction A with respect to a center axis 1106, or change the path of the light L incident in the first direction (X direction) to the second direction (Y direction) by rotating the center axis 1106 to a direction B. In this case, the OPFE 1110 may also be moved to the third direction (Z direction) perpendicular to the first direction (X direction) and the second direction (Y direction).

In some embodiments, as illustrated, the maximum rotation angle in a direction A of the prism 1105 may be about 15 degrees or less in a positive (+) direction A, and may be greater than about 15 degrees in a negative (−) direction A, but the embodiments are not limited thereto.

In some embodiments, the prism 1105 may be moved within about 20 degrees, or between about 10 degrees and about 20 degrees, or between about 15 degrees and about 20 degrees in a positive (+) or (−) direction B, and in this case, the movement degrees may be the same degrees in the positive (+) or the negative (−) direction B, or almost similar degrees thereto within a range of about 1 degree.

In some embodiments, the prism 1105 may move the reflective surface 1107 to the third direction (Z direction) in parallel with an extended direction of the center axis 1106.

The OPFE 1110 may include, for example, an optical lens including m (wherein m is a natural number) groups. The m optical lenses may move in the second direction (Y direction), and change an optical zoom ratio of the camera module 1100b. For example, when a basic optical zoom ratio of the camera module 1100b is defined as Z, and m optical lenses included in the OPFE 1110 are moved, the optical zoom ratio of the camera module 1100b may be changed to an optical zoom ratio of 3Z, 5Z, or more.

The actuator 1130 may move the OPFE 1110 and/or an optical lens thereof to a certain position. For example, the actuator 1130 may adjust a location of the optical lens so that an image sensor 1142 is at a focal length of the optical lens for an accurate sensing.

The image sensing device 1140 may include an image sensor (sensor) 1142, a control logic (logic) 1144, and a memory 1146. The sensor 1142 may sense an image of a sensing target by using the light L provided via the optical lens. The logic 1144 may control the overall operation of the camera module 1100b. For example, the logic 1144 may control an operation of the camera module 1100b according to a control signal provided via a control signal line CSLb.

The memory 1146 may store information, such as calibration data 1147, required for the operation of the camera module 1100b. The calibration data 1147 may include information required by the camera module 1100b for generating image data by using the light L provided from the outside. The calibration data 1147 may include, for example, information about the degree of rotation described above, information about the focal length, information about the optical axis, etc. When the camera module 1100b is implemented in a multi-state camera type, in which the focal length varies depending on the position of the optical lens, the calibration data 1147 may include information about a focal length value per position (or per state) of the optical lens and information about auto-focusing.

The storage 1150 may store the image data sensed by the image sensor 1142. The storage 1150 may be arranged outside the image sensing device 1140, and may be implemented in a form, in which the storage 1150 is stacked with a sensor chip constituting the image sensing device 1140. In some embodiments, the storage 1150 may be implemented as an electrically erasable programmable read-only memory (ROM) (EEPROM), but the present disclosure is not limited thereto.

Referring to FIGS. 11 and 12 together, in some embodiments, each of the plurality of camera modules 1100a, 1100b, and 1100c may include the actuator 1130. Accordingly, each of the plurality of camera modules 1100a, 1100b, and 1100c may include identical or different calibration data 1147 to or from each other, according to an operation of the actuator 1130 included therein.

In some embodiments, one camera module (for example, 1100b) of the plurality of camera modules 1100a, 1100b, and 1100c may include a folded lens-type camera module including the prism 1105 and the OPFE 1110 described above, and the remaining camera modules (for example, 1100a and 1100c) may include a vertical type camera module, which does not include the prism 1105 and the OPFE 1110, but the present disclosure is not limited thereto.

In some embodiments, one camera module (for example, 1100c) of the plurality of camera modules 1100a, 1100b, and 1100c may include a depth camera of a vertical type, in which depth information is extracted by using, for example, infrared ray (IR). In this case, the application processor 1200 may generate a three-dimensional (3D) depth image by merging image data provided by the depth camera with image data provided by another camera module (for example, 1100a or 1100b).

In some embodiments, at least two camera modules (for example, 1100a and 1100b) of the plurality of camera modules 1100a, 1100b, and 1100c may have different field of views from each other. In this case, for example, the optical lenses of at least two camera modules (for example, 1100a and 1100b) among the plurality of camera modules 1100a, 1100b, and 1100c may be different from each other, but the present disclosure is not limited thereto.

In addition, in some embodiments, the field of views of each of the plurality of camera modules 1100a, 1100b, and 1100c may be different from each other. In this case, the optical lenses included in each of the plurality of camera modules 1100a, 1100b, and 1100c may also be different from each other, but the present disclosure is not limited thereto.

In some embodiments, each of the plurality of camera modules 1100a, 1100b, and 1100c may be arranged physically apart from each other. In other words, a sensing area of one image sensor 1142 may not be divided and used by the plurality of camera modules 1100a, 1100b, and 1100c, but an image sensor 1142 (e.g., a respective image sensor 1142) may be arranged independently inside each of the plurality of camera modules 1100a, 1100b, and 1100c.

Referring again to FIG. 11, the application processor 1200 may include an image processing device 1210, a memory controller 1220, and an internal memory 1230. The application processor 1200 may be implemented isolated or separated from the plurality of camera modules 1100a, 1100b, and 1100c. For example, the application processor 1200 and the plurality of camera modules 1100a, 1100b, and 1100c may be implemented isolated or separated from each other in isolated or separated semiconductor chips.

The image processing device 1210 may include a plurality of sub-image processors (sub processors) 1212a, 1212b, and 1212c, an image generator 1214, and a camera module controller 1216.

The image processing device 1210 may include the plurality of sub processors 1212a, 1212b, and 1212c having the number thereof corresponding to the number of the plurality of camera modules 1100a, 1100b, and 1100c.

The image data generated by each of the plurality of camera modules 1100a, 1100b, and 1100c may be provided to corresponding plurality of sub processors 1212a, 1212b, and 1212c via image signal lines ISLa, ISLb, and ISLc which may be isolated or separated from each other. For example, the image data generated by the camera module 1100a may be provided to the sub processor 1212a via an image signal line ISLa, the image data generated by the camera module 1100b may be provided to the sub processor 1212b via an image signal line ISLb, and the image data generated by the camera module 1100c may be provided to the sub processor 1212c via the image signal line ISLc. Transmission of the image data may be performed by using, for example, a camera serial interface (CSI) based on a mobile industry processor interface (MIPI), but the embodiment is not limited thereto.

On the other hand, in some embodiments, one sub-image processor may also be arranged to correspond to a plurality of camera modules. For example, the sub processor 1212a and the sub processor 1212c may not be implemented as isolated or separated from each other as illustrated, but may be implemented as integrated into one sub-image processor, and the image data provided by the camera module 1100a and the camera module 1100c may, after being selected by a selection element (for example, a multiplexer) or the like, be provided to the integrated sub-image processor.

The image data provided to each of the plurality of sub processors 1212a, 1212b, and 1212c may be provided to the image generator 1214. The image generator 1214 may generate an output image by using the image data provided by each of the plurality of sub processors 1212a, 1212b, and 1212c according to image generation information or a mode signal.

The image generator 1214 may generate an output image by merging at least some of the image data generated by the plurality of camera modules 1100a, 1100b, and 1100c having different field of views from each other, according to the image generation information or the mode signal. In addition, the image generator 1214 may generate an output image by selecting at least one of the image data generated by the plurality of camera modules 1100a, 1100b, and 1100c having different field of views from each other, according to the image generation information or the mode signal.

In some embodiments, the image generation information may include a zoom signal or a zoom factor. In addition, in some embodiments, the mode signal may include, for example, a signal based on a mode selected by a user.

When the image generation information includes the zoom signal (zoom factor), and each of the plurality of camera modules 1100a, 1100b, and 1100c has different field of views from each other, the image generator 1214 may perform different operations from each other according to types of the zoom signals. For example, when the zoom signal includes a first signal, after merging the image data output by the camera module 1100a with the image data output by the camera module 1100c, the image generator 1214 may generate an output image by using the merged image signal with the image data output by the camera module 1100b which has not been used in the merging. When the zoom signal includes a second signal different from the first signal, the image generator 1214 may not perform the merging operation on the image data, but may generate the output image by selecting any one of the image data output by each of the plurality of camera modules 1100a, 1100b, and 1100c. However, the present disclosure is not limited thereto, and methods of processing the image data (including other methods) may be modified and performed as necessary.

In some embodiments, by receiving a plurality of image data having different exposure times from each other from at least one of the plurality of sub-image processors 1212a, 1212b, and 1212c, and performing a high dynamic range (HDR) processing on the plurality of image data, the image generator 1214 may generate the merged image data with an increased dynamic range.

The camera module controller 1216 may provide a control signal to each of the plurality of camera modules 1100a, 1100b, and 1100c. The control signal generated by the camera module controller 1216 may be provided to the corresponding plurality of camera modules 1100a, 1100b, and 1100c via control signal lines CSLa, CSLb, and CSLc, which may be isolated or separated from each other.

Any one of the plurality of camera modules 1100a, 1100b, and 1100c may be designated as a master or primary camera module (for example, 1100b) according to the image generation information including the zoom signal or the mode signal, and the other camera modules (for example, 1100a and 1100c) may be designated as slave or secondary camera modules. These pieces of information may be included in the control signal, and may be provided to the corresponding plurality of camera modules 1100a, 1100b, and 1100c via the control signal lines CSL1, CSLb, and CSLc.

According to a zoom factor or an operation mode signal, camera modules operating as the master camera module and the slave camera module may be changed. For example, when the field of view of the camera module 1100a is wider than the field of view of the camera module 1100b, and indicates a zoom ratio having a low zoom factor, the camera module 1100b may operate as the master camera module, and the camera module 1100a may operate as the slave camera module. On the other hand, when the field of view indicates a zoom ratio having a high zoom ratio, the camera module 1100a may operate as the master camera module, and the camera module 1100b may operate as the slave camera module.

In some embodiments, the control signal provided by the camera module controller 1216 to each of the plurality of camera modules 1100a, 1100b, and 1100c may include a sync enable signal. For example, when the camera module 1100b is the master camera module, and the camera modules 1100a and 1100c are the slave camera modules, the camera module controller 1216 may transmit the sync enable signal to the camera module 1100b. The camera module 1100b having received the sync enable signal may generate a sync signal based on the received sync enable signal, and provide the generated sync signal to the camera modules 1100a and 1100c via a sync signal line SSL. The camera module 1100b and the camera modules 1100a and 1100c may be synchronized to the sync signal, and transmit the image data to the application processor 1200.

In some embodiments, the control signal provided by the camera module controller 1216 to the plurality of camera modules 1100a, 1100b, and 1100c may include mode information according to the mode signal. Based on the mode information, the plurality of camera modules 1100a, 1100b, and 1100c may operate in a first operation mode and a second operation mode with respect to a sensing speed.

The plurality of camera modules 1100a, 1100b, and 1100c may, in the first operation mode, generate the image signal at a first speed (for example, generate the image signal at a first frame rate), encode the generated image signal at a second speed greater than the first speed (for example, encode the generated image signal at a second frame rate greater than the first frame rate), and transmit the encoded image signal to the application processor 1200.

The application processor 1200 may store the received image signal, that is, the encoded image signal, in the internal memory 1230 equipped therein or in the external storage 1400 outside the application processor 1200, and then, may read and decode the encoded image signal from the internal memory 1230 or the external storage 1400, and may display the image data, that is generated based on the decoded image signal. For example, a sub-image processor corresponding to the plurality of sub processors 1212a, 1212b, and 1212c of the image processing device 1210 may perform decoding, and in addition, may perform an image processing on the decoded image signal.

The plurality of camera modules 1100a, 1100b, and 1100c may, in the second operation mode, generate the image signal at a third speed less than the first speed (for example, generate the image signal at a third frame rate less than the first frame rate), and transmit the image signal to the application processor 1200. The image signal provided to the application processor 1200 may include an un-encoded signal. The application processor 1200 may perform the image processing on the received image signal, or store the received image signal in the internal memory 1230 or the external memory 1400.

The PMIC 1300 may provide power, for example, a power voltage to each of the plurality of camera modules 1100a, 1100b, and 1100c. For example, the PMIC 1300 may, under the control of the application processor 1200, provide a first power to the camera module 1100a via a power signal line PSLa, provide a second power to the camera module 1100b via a power signal line PSLb, and provide a third power to the camera module 1100c via a power signal line PSLc.

The PMIC 1300 may, in response to a power control signal PCON from the application processor 1200, generate power corresponding to each of the plurality of camera modules 1100a, 1100b, and 1100c, and in addition, may adjust a level of the generated power. The power control signal PCON may include a power adjustment signal per operation mode of the plurality of camera modules 1100a, 1100b, and 1100c. For example, the operation mode may include a low power mode, and in this case, the power control signal PCON may include information about a camera module operating at the low power mode and information about a set power level. The levels of power provided to each of the plurality of camera modules 1100a, 1100b, and 1100c may be identical to or different from each other. In addition, the level of power may be dynamically changed.

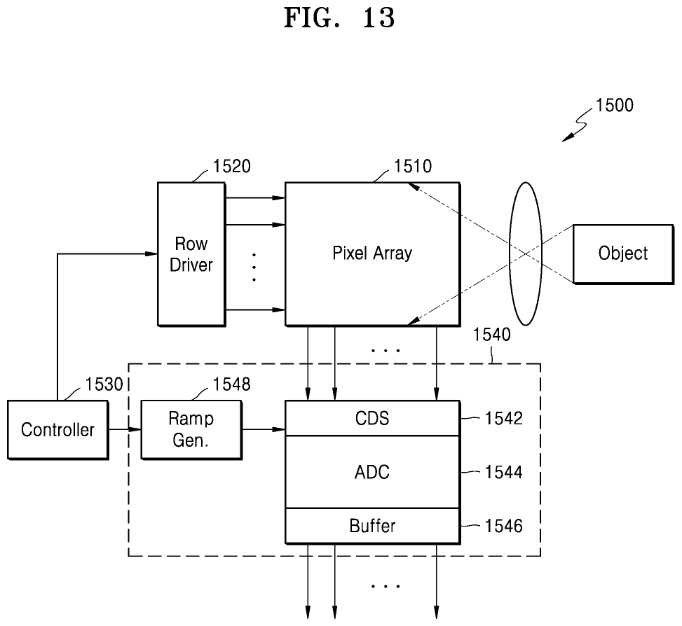

FIG. 13 is a block diagram of a configuration of an image sensor 1500, according to some embodiments.

Referring to FIG. 13, the image sensor 1500 may include a pixel array 1510, a controller 1530, a row driver 1520, and a pixel signal processor 1540.

The image sensor 1500 may include the image sensor 1 described above. The pixel array 1510 may include a plurality of unit pixels arranged two-dimensionally, and each unit pixel may include a photoelectric conversion element. The photoelectric conversion element may absorb light to generate photo charges, and an electrical signal (or an output voltage) according to the generated photo charges may be provided to the pixel signal processor 1540 via a vertical signal line.

The unit pixels included in the pixel array 1510 may provide one output voltage at a time in row units, and accordingly, the unit pixels belonging to one row of the pixel array 1510 may be activated simultaneously by a selection signal which is output by the row driver 1520. The unit pixel belonging to the selected row may provide the output voltage corresponding to the absorbed light, to an output line of a corresponding column.

The controller 1530 may control the row driver 1520 so that the pixel array 1510 absorbs light to accumulate the photo charges, temporarily store the accumulated photo charges, and/or output an electrical signal corresponding to the stored photo charges to the outside thereof. In addition, the controller 1530 may control the pixel signal processor 1540 to measure the output voltage provided by the pixel array 1510.

The pixel signal processor 1540 may include a correlated double sampler (CDS) 1542, an analog-to-digital converter (ADC) 1544, and a buffer 1546. The CDS 1542 may sample and hold the output voltage provided by the pixel array 1510.

The CDS 1542 may double-sample a certain noise level and a level of the generated output voltage, and output a level corresponding to a difference therebetween. In addition, the CDS 1542 may receive ramp signals generated by a ramp signal generator 1548, compare the ramp signals to each other, and output a result of the comparison.

The ADC 1544 may convert an analog signal corresponding to the level received from the CDS 1542 into a digital signal. The buffer 1546 may latch the digital signal, and the latched digital signal may be sequentially output to the outside of the image sensor 1500 and transferred to an image processor (not illustrated).

While the inventive concepts have been particularly shown and described with reference to some examples of embodiments thereof, it will be understood that various changes in form and details may be made therein without departing from the scope of the following claims.

What is claimed is:

1. An image sensor comprising:
a substrate including a first surface and a second surface, and including a plurality of photoelectric conversion elements therein;
a plurality of pixels provided in the substrate;
a plurality of pixel separation structures configured to separate the plurality of pixels; and
a plurality of contacts respectively connected to the plurality of pixel separation structures,
wherein a first contact among the plurality of contacts is configured to apply a current to a first portion of the plurality of pixel separation structures, and a second contact among the plurality of contacts is configured to detect a current from a second portion of the plurality of pixel separation structures.

2. The image sensor of claim 1, wherein the plurality of pixels comprise an active pixel region that defines the plurality of pixels and a dummy pixel region that surrounds the active pixel region, and
wherein the plurality of pixel separation structures comprise a pixel separation structure arranged in the active pixel region, and a first verification pixel separation structure and a second verification pixel separation structure arranged in the dummy pixel region.

3. The image sensor of claim 2, further comprising a pad region arranged on at least one side of the dummy pixel region and a verification wiring that electrically connects the plurality of contacts to the pad region,
wherein the verification wiring is configured to provide an applied bias voltage to the plurality of contacts.

4. The image sensor of claim 2, wherein the first verification pixel separation structure comprises a first conductive layer and a first pad,
wherein the first pad electrically connects the first conductive layer to the first contact,
wherein the second verification pixel separation structure comprises a second conductive layer and a second pad, and
wherein the second pad electrically connects the second conductive layer to the second contact.

5. The image sensor of claim 4, wherein the pixel separation structure comprises a conductive layer and a lower insulating layer,
wherein the conductive layer is arranged inside the pixel separation structure, and
wherein the lower insulating layer is arranged between the conductive layer and the first surface of the substrate, and comprises a material that is different from a material of the first pad and the second pad.

6. The image sensor of claim 4, wherein the first pad extends from the first surface of the substrate and into the first pixel separation structure, and
the second pad extends from the first surface of the substrate and into the second verification pixel separation structure.

7. The image sensor of claim 4, wherein the first pad comprises an material that is identical to a material of the first conductive layer, and
the second pad comprises an material that is identical to a material of the second conductive layer.

8. The image sensor of claim 4, wherein each of the first pad and the second pad is arranged to overlap vertically at least one photoelectric conversion element among the plurality of photoelectric conversion elements.

9. The image sensor of claim 1, wherein each of the plurality of pixel separation structures comprises a first insulating liner and a second insulating liner,
the first insulating liner is arranged on an inner wall of a pixel trench for the pixel separation structure that extends through the substrate, and
the second insulating liner is arranged inside the pixel trench, and extends from the first surface of the substrate to the second surface thereof.

10. An image sensor comprising:
a substrate including a first surface and a second surface, the substrate comprising a plurality of pixels and a plurality of photoelectric conversion elements therein, the substrate including an active pixel region that defines the plurality of pixels, a dummy pixel region that surrounds the active pixel region, and a pad region arranged on at least one side of the dummy pixel region;
an insulating layer arranged on the first surface;
a plurality of pixel separation structures that separate the plurality of pixels; and
a plurality of contacts respectively connected to the plurality of pixel separation structures, and extending through the insulating layer,
wherein the plurality of pixel separation structures comprise a pixel separation structure arranged in the active pixel region, and a first verification pixel separation structure and a second verification pixel separation structure arranged in the dummy pixel region,
wherein the first verification pixel separation structure comprises a first pad having at least a portion thereof extending into the substrate on the first surface,
wherein the second verification pixel separation structure comprises a second pad having at least a portion thereof extending into the substrate on the first surface,
wherein the first pad is electrically connected to a first contact, and the second pad is electrically connected to a second contact, and
wherein the first contact is configured to apply a bias voltage to the first verification pixel separation structure, and the second contact is configured to detect a current from the second verification pixel separation structure.

11. The image sensor of claim 10, wherein each of the first pad and the second pad is arranged to partially and vertically overlap at least four photoelectric conversion elements among the plurality of photoelectric conversion elements.

12. The image sensor of claim 10, wherein the first pad comprises a first horizontal portion inside the insulating layer and a first vertical portion inside the substrate,
wherein the second pad comprises a second horizontal portion inside the insulating layer and a second vertical portion inside the substrate,
wherein a horizontal width of the first horizontal portion in a first direction in parallel with the first surface is greater than a horizontal width of the first vertical portion in the first direction, and
wherein a horizontal width of the second horizontal portion in the first direction is greater than a horizontal width of the second horizontal portion in the first direction.

13. The image sensor of claim 12, wherein a horizontal width of the first vertical portion of the first pad decreases in a second direction vertical to the first direction, and a horizontal width of the second vertical portion of the second pad decreases in the second direction.

14. The image sensor of claim 12, wherein the first vertical portion of the first pad and the second vertical portion of the second pad have any one shape among a rectangular shape and a tapered shape.

15. The image sensor of claim 10, wherein the pixel separation structure is arranged between the first verification pixel separation structure and the second verification pixel separation structure.

16. The image sensor of claim 10, wherein each of the first contact and the second contact extends through the insulating layer.

17. The image sensor of claim 10, wherein the pixel separation structure comprises a lower insulating layer arranged on the first surface of the substrate, and
the pixel separation structure is insulated from the insulating layer by using the lower insulating layer.

18. An image sensor comprising:
a substrate including a first surface and a second surface, the substrate comprising a plurality of pixels and a plurality of photoelectric conversion elements therein, the substrate including an active pixel region that defines the plurality of pixels, a dummy pixel region that surrounds the active pixel region, and a pad region arranged on at least one side of the dummy pixel region;
a color filter arranged on the second surface of the substrate;
a reflection prevention layer arranged on the color filter;
a plurality of micro lenses arranged on the reflection prevention layer;
an insulating layer arranged under the first surface, and partially covering a first pad and a second pad;
an interlayer insulating layer arranged under the insulating layer, and configured to provide a path to output an electrical signal generated by the plurality of photoelectric conversion elements;
a plurality of pixel separation structures that separate the plurality of pixels, and including a pixel separation structure arranged in the active pixel region, and a first verification pixel separation structure and a second verification pixel separation structure arranged in the dummy pixel region; and
a plurality of contacts respectively connected to the plurality of pixel separation structures, and extending through the insulating layer and extending into the interlayer insulating layer,
wherein the first verification pixel separation structure comprises the first pad having at least a portion therein extending into the substrate on the first surface, and the second verification pixel separation structure comprises the second pad having at least a portion thereof extending into the substrate on the first surface, and
wherein the first pad is electrically connected to a first contact, the second pad is electrically connected to a second contact, the first contact is configured to apply a bias voltage to the first verification pixel separation structure, and the second contact is configured to detect a current from the second verification pixel separation structure.

19. The image sensor of claim 18, further comprising a first verification wiring and a second verification wiring which electrically connect the plurality of contacts to the pad region,
wherein the first verification wiring is configured to provide an applied bias voltage to the first contact, and wherein the second verification wiring is configured to provide a measurable leakage current from the substrate at the second contact.

20. The image sensor of claim 18, wherein the second contact is configured to detect the current prior to formation of the color filter, the reflection prevention layer, and the plurality of micro lenses.
